(19) United States
(12) Patent Application Publication
(10) Pub. No.: US 2024/0198392 A1
(43) Pub. Date: Jun. 20, 2024

(54) PRESSURE WASHER

(71) Applicant: TECHTRONIC CORDLESS GP, Anderson, SC (US)

(72) Inventors: Sven ESCHRICH, Dongguan (CN); Shao Kang YANG, Dongguan (CN); Jia Wei XIE, Dongguan (CN)

(21) Appl. No.: 18/082,158

(22) Filed: Dec. 15, 2022

(30) Foreign Application Priority Data
Dec. 15, 2021 (CN) 202111537101.9

(51) Int. Cl. B08B 3/02; B05B 7/04; B05B 9/00; B05B 9/01

(52) U.S. Cl. CPC B08B 3/028; B05B 7/0408; B05B 9/007; B05B 9/01; B08B 2203/0235

(57) ABSTRACT

Provided in the present invention is a pressure washer (100, 200), including: a frame (5); a power unit (1, 1A) supported by the frame; a pump (13, 33), supported by the frame, driven by the power unit, and used to pressurize an influent fluid so as to output a pressurized fluid; a jetting gun (2, 2A), configured to receive the pressurized fluid outputted by the pump and jet the pressurized fluid; and a controller (23, 23A), connected to the power unit (1, 1A) and used to control operation of the pressure washer. The pressure washer is characterized in that: the controller (23, 23A) includes a heat sink (18, 38) used to dissipate heat from the controller, and the heat sink (18, 38) includes a heat sink body, and is provided with a fluid tube (16a, 17a, 36) so as to perform fluid-based heat dissipation. The present invention proposes using a fluid (e.g., water or water containing a cleanser) flowing through the pressure washer to perform fluid-based cooling on the heat sink of the controller, so as to reasonably utilize resources and improve heat dissipation performance.

### TECHNICAL FIELD

The present invention relates to a pressure washer, and in particular to a heat sink for a controller of a pressure washer.

### BACKGROUND

A pressure washer is also referred to as a pressure washing device, is typically used to provide a continuous flow of pressurized fluid to an operation surface or an object, so as to wash the operation surface or the object to peel off and wash off dirt, thereby achieving the purpose of recovering a clear object surface. The pressure washer is widely applied to various fields of life. A pressure washer is a cleaning apparatus that can produce a high pressure water flow to wash an object surface, is widely applied to various fields of life and work, particularly to processes of cleaning outdoor yards, motor lanes, walkways, etc. having concrete structure surfaces and processes of cleaning tracks, fences, automobiles, etc. having hard surfaces, and has good cleaning performance. In daily life, when a pressure washer is used to clean an object surface having stains, in order to ensure cleaning performance, a pressure washer provided with a cleanser container is typically used. A detergent or a chemical solvent is contained in the cleanser container as a cleanser, and is jetted to the object surface by a jetting gun on the pressure washer, so that the stains on the object surface are quickly dissolved and peeled off under the action of the cleanser and the pressure of water flow, thereby improving the cleaning performance of the pressure washer.

The pressure washer typically includes a pump used to increase the pressure of a provided fluid, and a power source for providing power for operation of the pump. The power source typically includes: an internal combustion engine burning, for example, gasoline or natural gas, or an electric machine using an alternating current or a direct current. An output shaft of the internal combustion engine or the electric machine is connected to the pump, thereby providing power for driving the pump. A prior art pressure washer typically includes an electronic controller for controlling operation of the internal combustion engine or the electric machine so as to drive the pump to generate a pressurized fluid. The controller produces a large amount of heat when controlling the internal combustion engine or the electric machine to operate, and typically includes a heat sink made of, for example, a metal so as to perform heat dissipation, thereby ensuring that the pressure washer operates stably. When power of the washer is high, the heat dissipation performance of the heat sink may not be satisfactory.

### SUMMARY

To improve heat dissipation performed on the controller, the present invention proposes using a fluid flowing through a pressure washer to perform fluid-based cooling on a heat sink of a controller therein, so as to reasonably utilize resources and improve heat dissipation performance.

According to the above inventive concept, provided in the present invention is a pressure washer, comprising: a frame; a power device supported by the frame; a pump, driven by the power device, and used to pressurize an inputted fluid so as to output a pressurized fluid; a jetting gun, configured to receive the pressurized fluid outputted by the pump and jet the pressurized fluid; and a controller, connected to the power device and used to control operation of the pressure washer, wherein the controller comprises a heat sink used to dissipate heat from the controller, and the heat sink comprises a heat sink body, and is provided with a fluid tube so as to perform fluid-based heat dissipation.

Further provided in the present invention is a controller for an electric machine or a motor, the electric machine or motor being used to drive a pump, the pump being used to receive a fluid and pump the fluid out, the controller comprising a printed circuit board and electronic components, and the electronic components being mounted on the printed circuit board and electrically connected to each other, wherein the controller comprises a heat sink used to dissipate heat from at least some of the electronic components of the controller, and the heat sink comprises a heat sink body, and is provided with a fluid tube so as to perform fluid-based heat dissipation.

In an embodiment, the pump comprises a fluid inlet and a fluid outlet, the fluid inlet being connected to a fluid source located outside the pressure washer by means of a fluid pipe, the fluid outlet being connected to the jetting gun by means of a fluid pipe, and the fluid tube of the heat sink being in fluid communication with the fluid inlet or the fluid outlet of the pump so as to utilize the fluid inputted into the pump or the pressurized fluid outputted by the pump or at least part of the fluid to perform the fluid-based heat dissipation.

In an embodiment, the fluid tube comprises at least one water input section and at least one water output section, and the at least one water input section and the at least one water output section are located on the same side of the heat sink, respectively act as a fluid input end and a fluid output end of the fluid tube, and communicate with one of the fluid inlet and the fluid outlet of the pump.

Alternatively, the fluid tube comprises at least one water input section and at least one water output section, and the at least one water input section and the at least one water output section are located on different sides, preferably opposite sides, of the heat sink, and respectively act as a fluid input end and a fluid output end of the fluid tube, the at least one water input section communicating with the fluid outlet of the pump, or the at least one water output section communicating with the fluid inlet of the pump.

In an embodiment, the fluid tube further comprises at least one intermediate section communicating with the at least one water input section and the at least one water output section, and the at least one intermediate section is at least partially located inside the heat sink body of the heat sink, and preferably extends substantially along a straight line.

Preferably, the at least one intermediate section comprises a first intermediate section in fluid communication with the at least one water input section and a second intermediate section in fluid communication with the at least one water output section, preferably the first intermediate section and the second intermediate section at least partially overlapping in a fluid flow direction, more preferably the first intermediate section and the second intermediate section substantially completely overlapping in the fluid flow direction, and more preferably the first intermediate section and the second intermediate section being parallel in the fluid flow direction.

Preferably, the heat sink body provides an inlet to the at least one intermediate section, and the inlet is selectively sealed by a sealing member.

In an embodiment, the heat sink body comprises a heat dissipation surface, and at least part of the controller is mounted on the heat dissipation surface, preferably the controller comprising a printed circuit board, and the printed circuit board being mounted on the heat dissipation surface.

Preferably, part of the printed circuit board and the at least one intermediate section overlap, and are preferably respectively located on two opposite sides of the heat dissipation surface.

In an embodiment, the controller comprises electronic components, and at least some of the electronic components comprise power semiconductor devices, the power semiconductor devices and the at least one intermediate section overlapping, and being preferably respectively located on two opposite sides of the heat dissipation surface, preferably the power semiconductor devices in the controller comprising a metal-organic field-effect transistor (MOSFET), a thyristor, and an insulated-gate bipolar transistor (IGBT), and more preferably the thyristor being a gate turn-off thyristor (GTO).

In an embodiment, the controller comprises a housing so as to accommodate the electronic components of the controller, and the heat sink is located in the housing or forms part of the housing, preferably the housing being made of a metal or any other thermally conductive material.

Preferably, the housing is located near the power device, and the power device comprises an air-cooled module to facilitate heat dissipation of the housing.

Preferably, the power device comprises a fan driven by a motor, and the fan and the housing are axially adjacent to each other.

In an embodiment, the power device comprises an oil fuel engine, a gas engine, or a fuel engine, or comprises an electric motor powered by an AC power supply, a DC power supply, or a battery, and preferably, the pump is driven by the power device by means of a transmission, the power device comprising an outer housing covering thereon.

In an embodiment, the pressure washer further comprises wheels and a handle connected to the frame, so as to allow a user to move the pressure washer by means of the handle.

In an embodiment, the pressure washer further comprises a cleanser injection assembly and a cleanser container, the cleanser container being supported by the frame and being used to accommodate a cleanser solution, the cleanser injection assembly being configured to supply the cleanser solution to the pump by means of a pipe so as to mix the same with the inputted fluid or the pressurized fluid outputted by the pump, preferably the cleanser container being detachable or replaceable, and the cleanser container comprising an openable or detachable cover so as to allow the cleanser solution to be added to the cleanser container.

According to the present invention, a fluid inputted into a pressure washer can be utilized to perform fluid-based cooling on a heat sink in a controller of the pressure washer, thereby achieving improved heat dissipation performance. In addition, the fluid is, for example, tap water, and is jetted by the pressure washer. In this way, the present invention enables reasonable utilization of resources without incurring additional costs.

### BRIEF DESCRIPTION OF THE DRAWINGS

FIG. 1A shows a pressure washer according to some embodiments of the present invention.

FIG. 1B shows a schematic partial exploded view of the pressure washer in FIG. 1A.

FIG. 2 shows a power device of a pressure washer according to some embodiments of the present invention.

FIG. 3 shows a power device of a pressure washer according to some embodiments of the present invention.

FIG. 4 shows a sectional view of a heat sink for a controller of a power device of a pressure washer according to some embodiments of the present invention.

FIG. 5A shows a pressure washer according to another embodiment

of the present invention.

FIG. 5B shows a schematic partial exploded view of the pressure washer in FIG. 5A.

FIG. 6 shows a power device of a pressure washer according to another embodiment of the present invention.

FIG. 7 shows a controller of a power device of a pressure washer according to another embodiment of the present invention.

### DETAILED DESCRIPTION

Specific embodiments of the present invention are described in further detail below with reference to the accompanying drawings.

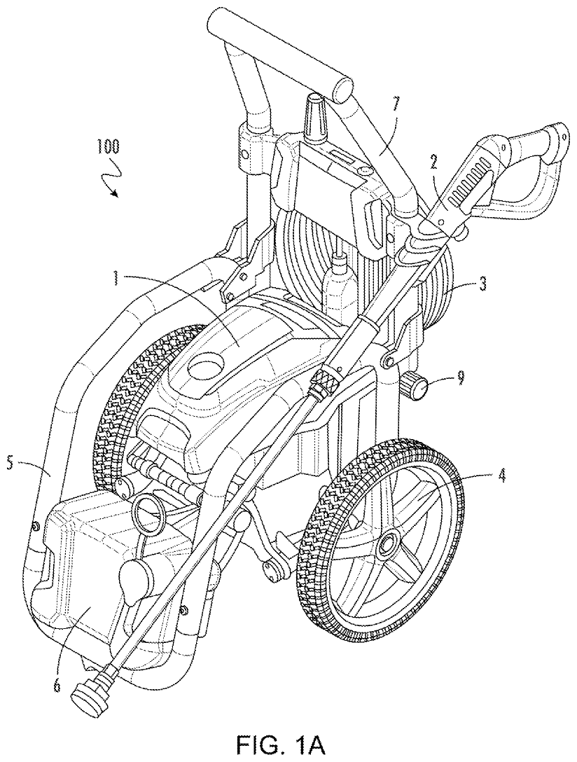

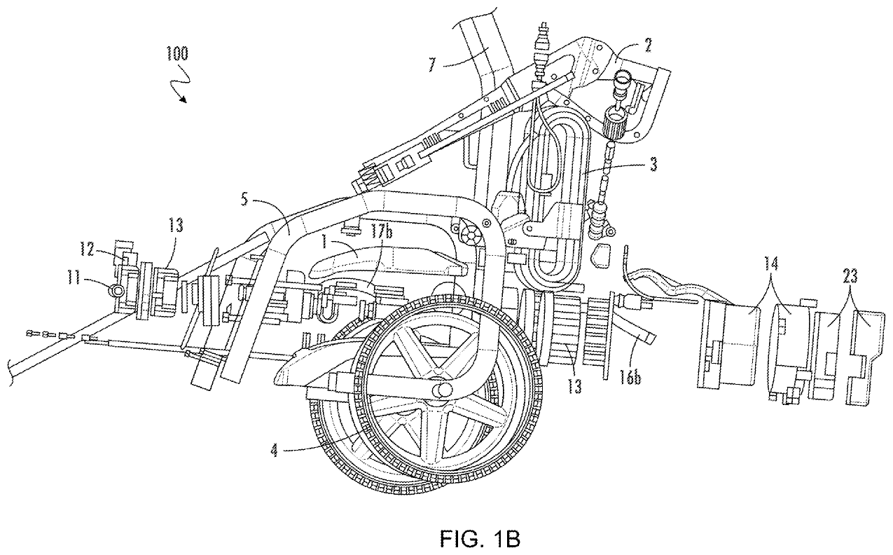

FIGS. 1A and 1B show a pressure washer according to some embodiments of the present invention.

As shown in FIG. 1A, a pressure washer 100 of the present invention includes a frame 5, an operating unit 1 supported by the frame 5, and a jetting gun 2. The operating unit 1 of the pressure washer 100 receives an inputted fluid and pressurizes the same to acquire a pressurized fluid, and may be fixedly mounted on the frame 5 by means of, for example, a screw. In some embodiments, the operating unit 1 further mixes the received fluid with a cleanser to acquire a pressurized cleaning fluid. The jetting gun 2 receives the pressurized fluid outputted by the operating unit 1, and jets the pressurized fluid. The fluid is, for example, water. In some embodiments, the fluid may be tap water from a municipal water supply network. The pressure washer 100 may be connected to a water source by means of, for example, a plastic pipe 3 so as to acquire the fluid. The plastic pipe 3 includes a connector 9 connected to the pressure washer. The plastic pipe 3 may be attached to the pressure washer 100 for ease of carrying.

The plastic pipe 3 is preferably an elastic coiled hose, so that when an operator operates the pressure washer 100, the hose can be coiled and uncoiled automatically. This can improve convenience, and prevent operation from being disturbed by the plastic pipe 3. The jetting gun 2 and the operating unit 1 may be connected to each other by means of a high-pressure hose. The jetting gun 2 (or the operating unit 1) and the high-pressure hose are connected to each other via a connection device having, for example, a threaded connection or a quick connection. The connection device having a quick connection may also be of a pin connection type. The high-pressure hose is preferably a long hose, and as shown in FIG. 1A, the hose may be coiled in a storage coiler. The hose may also be stored by using a hose reel, a plastic tray, a hook, a bracket, a hooked or endless belt, or other devices.

The jetting gun 2 may include a conventional fluid valve or manifold valve. The fluid valve or manifold valve may be located in a handle portion of the jetting gun, and may be controlled by a trigger having a safety latch. When the trigger is triggered, the fluid flows through the valve and the jetting gun 2. When the trigger is in an untriggered state, flowing of the fluid is stopped, and the fluid does not flow through the jetting gun 2. Preferably, the trigger is located near the handle of the jetting gun, so that a user holding the handle can easily trigger the trigger.

In some embodiments, the pressure washer 100 may further include wheels 4 and a handle 7 connected to the frame 5, so as to allow a user to move the pressure washer 100 by means of the handle 7. Two, three, four, or more wheels may be provided. The pressure washer 100 may further include a driving mechanism used to drive the wheels to rotate, so as to flexibly move forwards, turn, or reverse.

The frame 5 and/or the handle 7 may be made of a material such as metal, plastic, etc.

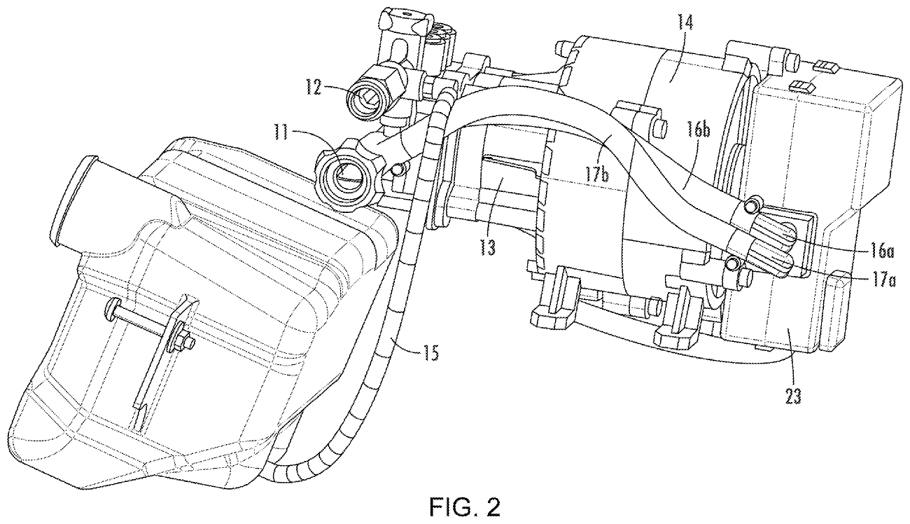

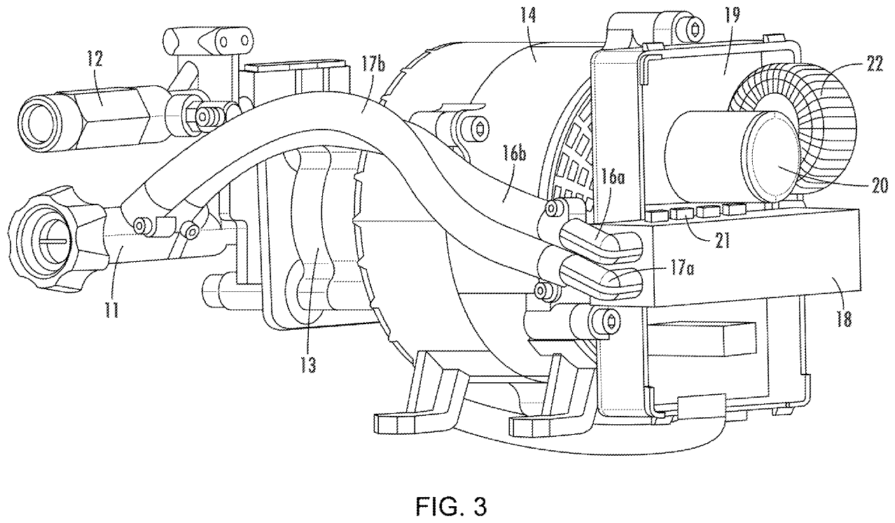

The pressure washer 100 may further include a cleanser container 6 and a cleanser injection assembly. The cleanser container 6 is supported by the frame 5, and is used to accommodate a cleanser. The cleanser container is isolated from external air, and is capable of being pressurized to at least the pressure of the fluid source. The cleanser injection assembly is configured to supply the cleanser to a pump 13 of the operating unit 1 by means of a cleanser pipe 15 (see FIG. 2 and FIG. 3), so as to mix the same with a fluid inputted into the pump 13 or a pressurized fluid outputted by the pump 13, thereby acquiring the cleaning fluid. The above mixing may be preferably implemented on the basis of Bernoulli's principle. Some cleanser injectors are pump down-stream (i.e., downstream) venturi valves. The pump down-stream venturi valve is activated when the user selects a low-pressure spray nozzle. Some other pump down-stream cleanser injectors include high-pressure spray nozzles having valves, and the valves are used as high-pressure venturi valves at jetting points. The pressure washer may use the venturi effect to draw the cleanser into fluid flow. The technique of using a venturi tube to introduce a second fluid, such as a cleanser, into a first fluid (e.g., water) is well known. The second fluid is introduced by a suction device inlet typically aligned with a narrowed portion of the venturi tube or located downstream of the venturi tube. During operation, the second fluid to be introduced is drawn into the venturi tube by means of the suction device inlet when the fluid flows through the venturi tube. For a given venturi tube, the suction rate depends on the flow rate of a fluid flowing through an inlet of the venturi tube and the viscosity of the fluid.

As shown in FIG. 2, the cleanser pipe 15 is connected to an input pipe 11 of the pump 13 or an output pipe 11 from the pump 13, so that pressure generated by flowing of the fluid drives the cleanser to flow, and the fluid and the cleanser are mixed. Preferably, the cleanser container 6 is detachable or replaceable, and includes an openable or detachable cover so as to allow the cleanser to be added or replenished to the cleanser container 6. The cleanser container 6 may typically be made of a metal, plastic, etc. The cleanser container may be supported by the frame or a device extension component, and may have a substantially cuboid shape. Each surface of the cleanser container has a slot or rib for facilitating mounting and fixing, and each corner of the cleanser container may be rounded.

FIG. 1B shows a schematic partial exploded view of the pressure washer in FIG. 1A, and FIG. 2 shows the operating unit 1 of the pressure washer 100 according to some embodiments of the present invention. As shown in FIG. 1B and FIG. 2, the operating unit 1 may include a power device 14, a controller 23, the pump 13, and a line in fluid communication with the pump. FIG. 3 shows a perspective view of the operating unit 1. In order to more clearly show the internal structure of the controller 23, part of a housing of the controller 23 is omitted so as to show a printed circuit board 19, electronic components 20-22, and a heat sink 18 therein.

Preferably, the power device 14 of the operating unit 1 is supported by the frame 5, and may be, for example, an oil fuel engine, a gas engine, or a fuel engine, or an electric motor powered by an AC power supply or a DC power supply. The power device 14 may be accommodated in an outer housing. When the power device 1 is an electric motor, the pressure washer 100 may further include a battery for powering the electric motor, such as a detachable or replaceable rechargeable battery.

Preferably, the pump 13 is supported by the frame 5, and is driven by the power device 14. The pump 13 is used to pressurize an inputted fluid into a pressurized fluid. Preferably, the pump is driven by the power device 14 by means of a transmission. The transmission may include a gear train, a belt, or the like. The pump 13 is typically used as a fluid pump, provides a flow rate, for example, between about 2 liters/minute (l/min) and 20 l/min, and provides pressure, for example, between about 70 kg/cm² and 350 kg/cm². However, other ranges may also be used. As shown in FIG. 2, the pump 13 is located on the left of the power device 14. However, other arrangements may also be used. For example, the pump 13 may be located below the power device 14, and may be driven by means of a transmission.

The controller 23 is electrically connected to the power device 1, and is used to control operation of the power device 1. In some embodiments, the controller 23 may also control other components of the pressure washer 100, such as the jetting gun, or the controller 23 may receive control inputs from other components of the pressure washer 100, such as the jetting gun. The controller 23 includes the heat sink 18 used to dissipate heat from the controller, particularly from high-voltage or large-current electronic components (e.g., power semiconductor devices 21) in the controller 23. The heat sink 18 includes a heat sink body, and is provided with a fluid tube so as to perform fluid-based heat dissipation.

In some embodiments, the pump 13 includes a fluid inlet 12 and a fluid outlet 11. The fluid inlet 12 is connected to a fluid source located outside the pressure washer 100 by means of a fluid pipe, and the fluid outlet 11 is connected to the jetting gun 2 by means of a fluid pipe. The fluid tube of the heat sink 18 of the controller 23 is in fluid communication with the fluid outlet 11 of the pump 13, so as to utilize the pressurized fluid outputted by the pump 13 or at least part thereof to perform the fluid-based heat dissipation.

In some embodiments, the fluid tube includes at least one water input section 16a and at least one water output section 17a. The at least one water input section 16a and the at least one water output section 17a are in fluid communication with the fluid inlet or the fluid outlet 11 of the pump 13 by means of fluid pipes 16b and 17b, respectively. In some embodiments, the fluid pipes 16b and 17b may be sequentially connected to the fluid inlet or the fluid outlet 11 in a fluid flow direction.

In some embodiments, the at least one water input section 16a and the at least one water output section 17b are located on the same side of the heat sink 18, and respectively act as a fluid input end and a fluid output end of the fluid tube of the heat sink. In some embodiments, the at least one water input section 16a and the at least one water output section 17b may be located on different sides, for example opposite sides or adjacent two sides, of the heat sink 18, and respectively act as the fluid input end and the fluid output end of the fluid tube of the heat sink. Preferably, a check valve may be provided in the fluid tube to prevent fluid reflux. In some embodiments, more than one water input section 16a, for example two, three, or more water input sections 16a, may be provided, and more than one water output section 17a, for example two, three, or more water output sections 17a, may be provided. The number of water input sections 16a and the number of water output sections 17a may be the same or different.

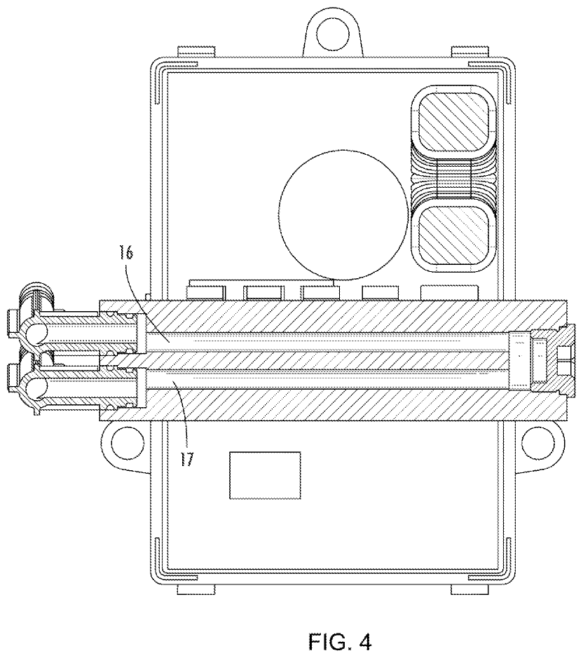

FIG. 4 shows a sectional view of the heat sink 18 for the controller 23 of the operating unit 1 according to the present invention. The heat sink 18 includes the heat sink body. The heat sink body defines a heat dissipation surface. The heat dissipation surface may include a plurality of surfaces, for example two opposite surfaces, of the heat sink body. The at least one water input section 16a and the at least one water output section 17b are connected to the heat sink body. In some embodiments, the fluid tube of the heat sink 18 may further include an intermediate section 16, 17 communicating with the at least one water input section 16a and the at least one water output section 17b. The at least one intermediate section 16, 17 is at least partially located inside the heat sink body, or in other words, extends in an internal space defined by the heat dissipation surface. In some embodiments, the at least one intermediate section 16, 17 is completely located inside the heat sink body. The at least one intermediate section may have various configurations. In some embodiments, the at least one intermediate section substantially extends along a straight line, or has other configurations, such as a wavy shape, a meandering shape, etc. The shape and path of the at least one intermediate section 16, 17 is configured to maximize a heat exchange area between the at least one intermediate section and the heat dissipation surface, so as to improve the heat dissipation efficiency of the heat sink.

In some embodiments, the at least one intermediate section includes a first intermediate section 16 in fluid communication with the at least one water input section 16a and a second intermediate section 17 in fluid communication with the at least one water output section 17a. The first intermediate section 16 is connected to the second intermediate section 17. The first intermediate section 16 and the second intermediate section 17 at least partially overlap in a fluid flow direction. In some embodiments, the first intermediate section 16 and the second intermediate section 17 substantially completely overlap in fluid flow direction. In some embodiments, the first intermediate section 16 and the second intermediate section 17 are parallel in the fluid flow direction.

In some embodiments, the fluid tube of the heat sink provides an opening to the outside. The opening is different from openings provided by the at least one water input section 16a and the at least one water output section 17a. The opening may be selectively sealed by a sealing member 18a. When the sealing member 18a is selectively opened, the opening exposes the interior of the fluid tube of the heat sink, such that operations such as cleaning can be performed. In some embodiments, the opening is provided in the heat sink body. In some embodiments, the opening is connected to at least one intermediate section. In some embodiments, the opening is provided at a connection location between the first intermediate section 16 and the second intermediate section 17.

In some embodiments, at least some electronic components 21 of the controller 23 are mounted on the heat dissipation surface directly or by means of a heat dissipation sheet, and are preferably fit to the heat dissipation surface. In some embodiments, the controller 23 includes the printed circuit board 19. The printed circuit board 19 is mounted on the heat dissipation surface directly or by means of a heat dissipation sheet, and is preferably fit to the heat dissipation surface. A plurality of electronic components 20, 22 may be provided on the printed circuit board 19. The electronic components 21 may be power semiconductor devices. When operating, the power semiconductor devices have high voltages and/or large currents and consume a large amount of energy, and a significant amount of heat may be generated. Fluid-based heat dissipation, such as water-cooled heat dissipation, is performed on the electronic components 21 having high energy consumption, thereby ensuring that the controller 23 and the pressure washer operate safely and effectively. For example, the power semiconductor devices may include a metal-organic field-effect transistor (MOSFET), a thyristor, an insulated-gate bipolar transistor (IGBT), etc. The thyristor may be a gate turn-off thyristor (GTO).

In some embodiments, the heat sink body has a cuboid configuration. The heat dissipation surface includes two opposite surfaces having maximum cross-sectional areas, and part or all of the electronic components 21 or the printed circuit board 19 is mounted on at least one of the two opposite surfaces. Preferably, the electronic components 21 or the printed circuit board 19 overlaps with the at least one intermediate section 16, 17.

In some embodiments, the controller 23 further includes a housing to enclose electronic components of the controller that are located on a surface of the heat sink and/or on a surface of the printed circuit board 19. The housing provides protection and water resistance for the electronic components. The heat sink 18 is located in the housing, or forms part of the housing. Preferably, the housing is made of a metal or any other thermally conductive material. In some embodiments, heat of the heat sink is transferred to a surface of the housing by means of heat conduction or convection, and the housing further facilitates heat dissipation.

In some embodiments, the controller 23 is located near the power device 1, and the power device 1 may further include an air-cooled module to facilitate heat dissipation of the housing. In some embodiments, the power device 1 may include a fan driven by an engine, an electric motor, or a motor, and the fan may be configured to be axially adjacent to the housing. The fan facilitates circulation of air near the housing of the controller, thereby further facilitating heat dissipation of the controller 23.

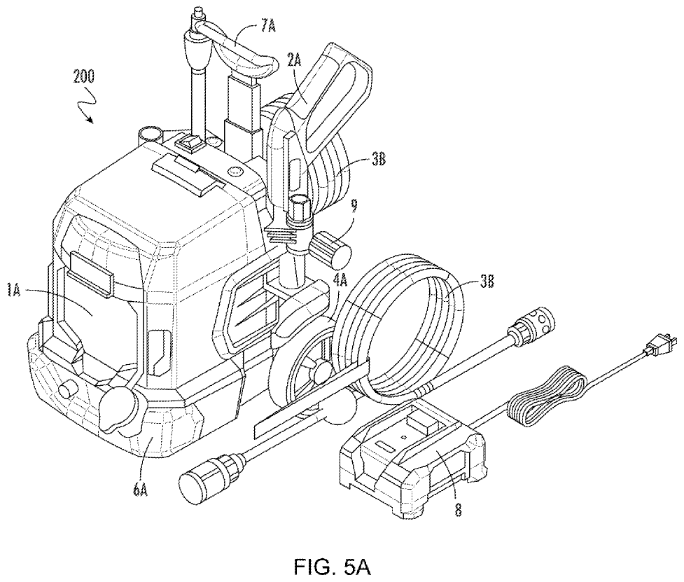

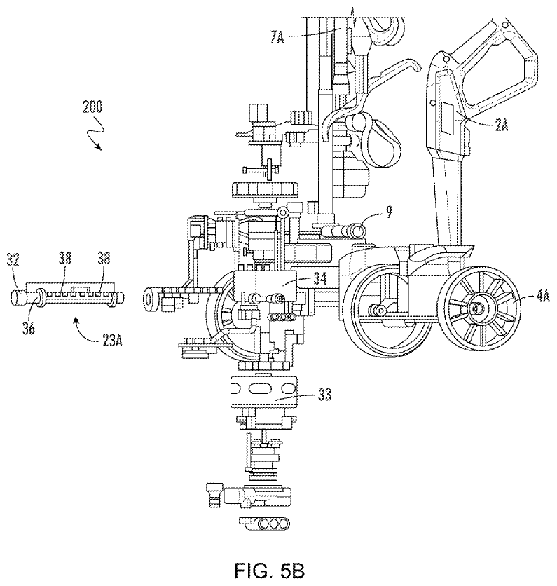

FIGS. 5A-7 show a pressure washer 200 according to some embodiments of the present invention.

As shown in FIG. 5A and FIG. 5B, the pressure washer 200 includes a frame, an operating unit 1A supported by the frame, and a jetting gun 2A. The operating unit 1A of the pressure washer 200 receives an inputted fluid, and pressurizes the same to acquire a pressurized fluid. In further embodiments, the operating unit 1A further mixes the received fluid with a cleanser to acquire a pressurized cleaning fluid. The jetting gun is configured by 2A to receive the pressurized fluid outputted by the operating unit 1A and to jet the pressurized fluid. The jetting gun may include a trigger, and triggering the trigger causes the pressurized fluid to be discharged from a nozzle. The fluid is, for example, water. In some embodiments, the fluid may be tap water from a municipal water supply network. A water faucet in an outdoor residential area supplies water having pressure about 2.8-5.6 kg/cm², and the supplied water is pressurized by the operating unit 1A. The pressurized fluid may be used for cleaning or other purposes. The pressure washer 200 may be connected to a water source by means of, for example, a plastic pipe 3A so as to acquire a fluid. The plastic pipe 3A is for connection to a connector 9 of the pressure washer. The plastic pipe 3A may be attached to the pressure washer 200 for ease of carrying.

FIG. 5B shows a schematic partial exploded view of the pressure washer in FIG. 5A. As shown in FIG. 5B, in this embodiment, the operating unit 1A includes a battery-powered electric motor, and may include a detachable or replaceable battery. The battery may be charged by means of a charger 8 separated from the pressure washer 200. Alternatively, the pressure washer of the present invention may include a charger and a charging interface, or may be connected to mains power supply or other power supplies so as to operate. The operating unit 1A may have an outer housing so as to cover components therein. For example, the electric motor is configured to receive power of, for example, 110 volts or 220 volts. The electric motor may generate any horsepower ranging from about 1 horsepower to about 7 horsepower, or more or less horsepower. In some embodiments, the electric motor may be powered separately, or alternatively, by a battery that may be a silver-cadmium battery or a lithium ion battery or any other battery capable of powering the electric motor. In the case that the operating unit 1A includes the battery, the pressure washer 200 may further include a circuit and a port for recharging the battery. An external power supply may be connected to the port to charge the battery. Alternatively, the battery may be detached from the pressure washer 200, and is charged by another charger device 8.

The electric motor may be a permanent magnet motor, a brushless DC motor, a switched reluctance motor, a cage or wound rotor induction motor, a torque motor, or an ironless/coreless rotor motor. The electric motor typically includes a housing, a stator assembly, a permanent magnet rotor assembly, a rotating shaft, an end cover, a fan for heat dissipation, etc.

The pressure washer 200 may also include wheels 4A and a handle 7A connected to the frame, so as to allow a user to move the pressure washer 200 by means of the handle 7A. As described above, two, three, four, or more wheels may be provided. The frame and/or the handle 7A may be made of a metal, plastic, etc. Alternatively, the pressure washer 200 further includes a driving mechanism used to drive the wheels to rotate, so as to flexibly move forwards, turn, or reverse.

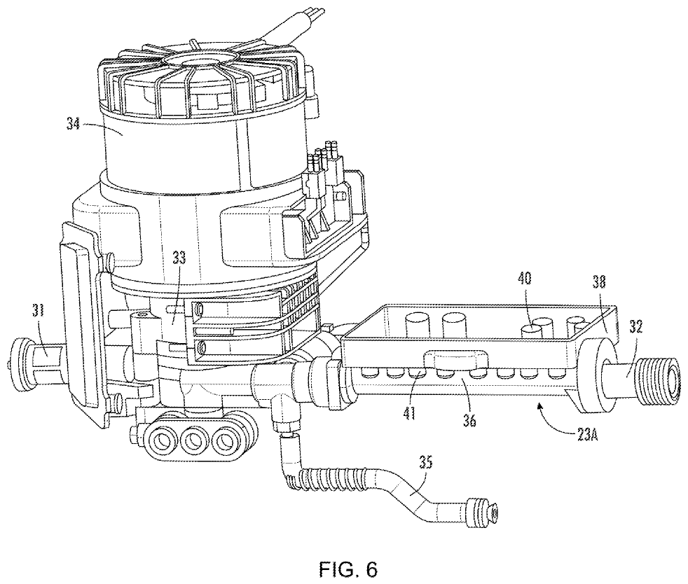

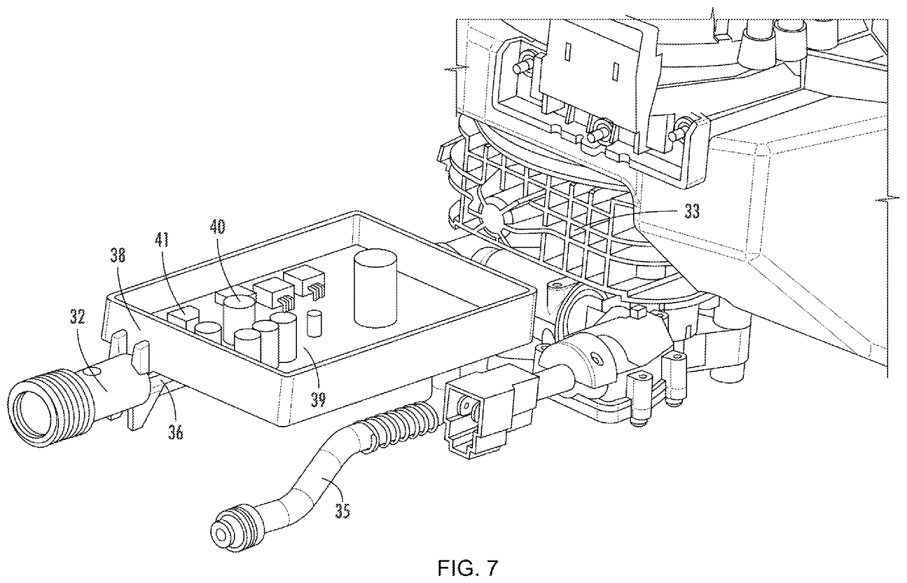

The pressure washer 200 may further include a cleanser container 6A and a cleanser injection assembly. The cleanser container 6A is supported by the frame, and is used to accommodate a cleanser solution. The cleanser injection assembly is configured to supply the cleanser solution to a pump 33 in the operating unit 1A by means of a cleanser pipe 35 (see FIG. 6 and FIG. 7), so as to mix the same with the inputted fluid or the pressurized fluid outputted by the pump, thereby acquiring a cleaning fluid. The above mixing may be preferably implemented on the basis of Bernoulli's principle. As shown in FIG. 7, the cleanser pipe 35 is connected to an output pipe of the pump 33, so that negative pressure generated by flowing of the fluid drives the cleanser to flow. Alternatively, in other embodiments, the cleanser pipe 35 may be connected to an input pipe 31 of the pump 33. Preferably, the cleanser container 6A is detachable or replaceable, thereby allowing an operator to easily detach and replace the cleanser container. Moreover, the cleanser container 6A may include an openable or detachable cover so as to allow the cleanser to be added or replenished to the cleanser container 6A. The cleanser container 6A may typically be made of a material such as metal, plastic, etc.

As shown in FIG. 6, the operating unit 1A may include an electric motor 34, a controller 23A, and a pump 33 powered by a battery or other power supplies. The controller 23A includes a printed circuit board 39, electronic components 40 and 41, and a heat sink 38. The electronic components 40 and 41 in the controller are connected to the electric motor 34, the pump 33, and other components (e.g., a jetting gun) of the pressure washer 200 by means of various connection lines so as to control operation thereof. The present invention does not alter the electronic components in the controller or a therebetween, and therefore the electronic connection relationship components in the controller and the connection relationship therebetween are merely schematically drawn in the drawings.

The pump 33 is driven by the electric motor 34, and is used to pressurize an inputted fluid into a pressurized fluid. Preferably, the pump 33 is driven by the electric motor 34 of the operating unit 1A by means of a transmission. The transmission may include components such as a gear or a belt or other driving members. Alternatively, the electric motor 34 may be directly engaged with the pump 33 without any additional power transmission system, and in this case the pump 33 may be a directly driven pump. For example, the electric motor 34 may include a rotatable output shaft connected to the pump 33 so to operate the pump 33 to pressurize a liquid to be pressurized.

The controller 23A is electrically connected to the electric motor 34, and is used to control operation of the pressure washer 200. The controller 23A may be configured to evaluate various operation and system integrity or operation control signals. For example, the controller 23A may monitor inlet pressure and/or pump temperature of the pump 33. The controller 23A includes a heat sink 38 used to dissipate heat from the controller 23A, particularly from high-voltage or large-current electronic components (e.g., power semiconductor devices 41) in the controller 23A. When operating, the high-voltage or large-current electronic components may generate a large amount of heat, so that heat dissipation needs to be performed to enable smooth operation of the pressure washer. The heat sink 38 includes a heat sink body, and is provided with a fluid tube 36 so as to perform fluid-based heat dissipation.

The pump 33 includes a fluid inlet 31. A fluid outlet of the pump is in fluid communication with the fluid tube 36, and an outlet 32 of the fluid tube 36 is connected to the jetting gun 2A by means of, for example, a fluid pipe. The fluid inlet 31 may be connected to a fluid source located outside the pressure washer 200 by means of a fluid pipe. In this way, the fluid tube 36 of the heat sink 38 may utilize the pressurized fluid outputted by the pump 33 or at least part of the pressurized fluid to perform the fluid-based heat dissipation. The fluid tube 36 may be a tube having, for example, a cylindrical shape, a prismatic shape, or any other shape, may be made of, for example, a metal or an alloy, and may include one or more tubes through which a fluid is allowed to pass. In an embodiment in which the fluid tube 36 includes a plurality of tubes, the tubes may have the same or different inner diameters, and may be interspersed or uniformly distributed in the fluid tube 36.

As shown in FIG. 6 and FIG. 7, according to the present invention, the heat sink 38 includes a heat sink body, the controller 23A includes a printed circuit board 39, and the printed circuit board 39 is mounted on a heat dissipation surface of the heat sink body.

Specifically, the controller 23A includes a plurality of electronic components 40, 41, and the electronic components 40, 41 are electrically connected to each other by means of the printed circuit board 39. Preferably, the electronic components 41 are power semiconductor devices. When operating, the power semiconductor devices have high voltages and/or large currents and consume a large amount of energy, and a significant amount of heat may be generated. Fluid-based heat dissipation, such as water-cooled heat dissipation, is performed on the electronic components having high energy consumption, thereby ensuring that the controller 23A and the pressure washer 200 operate safely and effectively. According to the present invention, a heat dissipation sheet of the electronic component 41 may be mounted on a heat dissipation surface adjacent to the fluid tube 36, so as to perform improved heat dissipation by means of the fluid tube 36. Preferably, the power semiconductor devices include, for example, a metal-organic field-effect transistor (MOSFET), a thyristor, an insulated-gate bipolar transistor (IGBT), etc., and more preferably the thyristor is a gate turn-off thyristor (GTO).

Preferably, the controller 23A includes a housing so as to accommodate the electronic components of the controller, and the heat sink 38 is located in the housing or forms part of the housing. Preferably, the housing is made of a metal or any other thermally conductive material.

Although the solution of the present invention is described in detail by using a pressure washer as an example, the heat sink employing fluid-based cooling of the present invention is also applicable to other devices. The devices include a pump and an electric machine or a motor used to drive the pump, and a controller of the electric machine or motor may use the heat sink employing fluid-based cooling of the present invention to perform fluid-based cooling by means of a fluid inputted into the pump and/or a fluid outputted by the pump or part of the fluid. The pump is used to receive a fluid and pump the fluid out. The controller includes a printed circuit board and electronic components. The electronic components are mounted on the printed circuit board, and are electrically connected to each other. The controller includes a heat sink used to dissipate heat from at least some of the electronic components of the controller. The heat sink includes a heat sink body, and is provided with a fluid tube so as to perform fluid-based heat dissipation by means of a fluid inputted into the pump and/or a fluid outputted by the pump or part of the fluid. The fluid may include water, water containing a cleanser, air, or other fluids.

Although the present invention has been described in detail with reference to a limited number of embodiments, it should be understood that the above detailed description should be considered as illustrative in nature, and non-limiting, and the present invention is not limited to these disclosed embodiments. It should be understood that the implementation of the present invention is not limited to the detailed structures or component arrangements provided in the description or illustrated in the accompanying drawings. The present invention may have other embodiments and can be achieved or implemented in a plurality of manners. Further, it should be understood that the terms or words used herein are for illustrative purposes only and should not be considered as limiting. The words “including,” “having,” and variations thereof used herein are meant to encompass the items listed thereafter and equivalents thereof, as well as other items. Unless otherwise stated or limited, the terms “mounting,” “connection,” “supporting,” and variations thereof are used in a broad sense, including direct or indirect mounting, connection, supporting, and attachment. Further, “connection” and “attachment” are not limited to physical or mechanical connection or attachment. Those of ordinary skill in the art may envisage other implementations that conform to the spirit and scope of the present invention, including changes of the number of components, alterations, substitutions, or equivalent arrangements, and these implementations all fall within the scope of the present invention.

1. A pressure washer, comprising: a frame a power device supported by the frame; a pump, driven by the power device, and used to pressurize an inputted fluid so as to output a pressurized fluid; a jetting gun, configured to receive the pressurized fluid outputted by the pump and jet the pressurized fluid; and a controller, connected to the power device and used to control operation of the pressure washer, wherein the controller comprises a heat sink used to dissipate heat from the controller, and the heat sink comprises a heat sink body, and is provided with a fluid tube to perform fluid-based heat dissipation.

2. The pressure washer according to claim 1, wherein the pump comprises a fluid inlet and a fluid outlet, the fluid inlet being connected to a fluid source located outside the pressure washer by means of a fluid pipe, the fluid outlet being connected to the jetting gun by means of a fluid pipe, and the fluid tube of the heat sink being in fluid communication with the fluid inlet or the fluid outlet of the pump so as to utilize the inputted fluid or the pressurized fluid outputted by the pump or at least part of the inputted fluid or the pressurized fluid to perform the fluid-based heat dissipation.

3. The pressure washer according to claim 2, wherein the fluid tube comprises at least one water input section and at least one water output section, and
the at least one water input section and the at least one water output section are located on the same side of the heat sink, respectively act as a fluid input end and a fluid output end of the fluid tube, and communicate with one of the fluid inlet and the fluid outlet of the pump.

4. The pressure washer according to claim 2, wherein the fluid tube comprises at least one water input section and at least one water output section, and the at least one water input section and the at least one water output section are located on different sides of the heat sink, and respectively act as a fluid input end and a fluid output end of the fluid tube, the at least one water input section communicating with the fluid outlet of the pump, or the at least one water output section communicating with the fluid inlet of the pump.

5. The pressure washer according to claim 3, wherein the fluid tube further comprises at least one intermediate section communicating with the at least one water input section and the at least one water output section, and the at least one intermediate section is at least partially located inside the heat sink body of the heat sink.

6. The pressure washer according to claim 3, wherein the at least one intermediate section comprises a first intermediate section in fluid communication with the at least one water input section and a second intermediate section in fluid communication with the at least one water output section.

7. The pressure washer according to claim 5, wherein the heat sink body provides an inlet to the at least one intermediate section, and the inlet is selectively sealed by a sealing member.

8. The pressure washer according to claim 5, wherein the heat sink body comprises a heat dissipation surface, and at least part of the controller is mounted on the heat dissipation surface.

9. The pressure washer according to claim 8, wherein part of the printed circuit board and the at least one intermediate section overlap.

10. The pressure washer according to claim 8, wherein the controller comprises electronic components, and the electronic components comprise power semiconductor devices, the power semiconductor devices and the at least one intermediate section overlapping.

11. The pressure washer according to claim 1, wherein the controller comprises a housing so as to accommodate the electronic components of the controller, and the heat sink is located in the housing or forms part of the housing.

12. The pressure washer according to claim 11, wherein the housing is located near the power device, and the power device comprises an air-cooled module to facilitate heat dissipation of the housing.

13. The pressure washer according to claim 11, wherein the power device comprises a fan driven by a motor, and the fan and the housing are axially adjacent to each other.

14. The pressure washer according to claim 1, wherein the power device comprises an oil fuel engine, a gas engine, or a fuel engine, or comprises an electric motor powered by an AC power supply, a DC power supply, or a battery.

15. The pressure washer according to claim 1, further comprising wheels and a handle connected to the frame, so as to allow a user to move the pressure washer by means of the handle.

16. The pressure washer according to claim 1, further comprising a cleanser injection assembly and a cleanser container, the cleanser container being supported by the frame and being used to accommodate a cleanser solution, the cleanser injection assembly being configured to supply the cleanser solution to the pump by means of a fluid pipe so as to mix the same with the inputted fluid or the pressurized fluid outputted by the pump.

17. A controller for an electric machine or a motor, the electric machine or motor being used to drive a pump, the pump being used to receive a fluid and pump the fluid out, the controller comprising a printed circuit board and electronic components, and the electronic components being mounted on the printed circuit board and electrically connected to each other, wherein the controller comprises a heat sink used to dissipate heat from at least some of the electronic components of the controller, and the heat sink comprises a heat sink body, and is provided with a fluid tube so as to perform fluid-based heat dissipation.

18. The controller according to claim 17, wherein the pump comprises a fluid inlet and a fluid outlet, and the fluid tube of the heat sink is in fluid communication with the fluid inlet side or the fluid outlet side of the pump, so as to utilize the inputted fluid or the fluid outputted by the pump or at least part of the fluid to perform the fluid-based heat dissipation.

19. The controller according to claim 18, wherein the fluid tube comprises at least one water input section and at least one water output section, and
the at least one water input section and the at least one water output section are located on the same side of the heat sink, respectively act as a fluid input end and a fluid output end of the fluid tube, and communicate with one of the fluid inlet and the fluid outlet of the pump.

20. The controller according to claim 18, wherein the fluid tube comprises at least one water input section and at least one water output section, and
at least one water input section and the at least one water output section are located on different sides.

21. The controller according to claim 19, wherein the fluid tube further comprises at least one intermediate section communicating with the at least one water input section and the at least one water output section, and the at least one intermediate section is at least partially located inside the heat sink body of the heat sink.

22. The controller according to claim 19, wherein the at least one intermediate section comprises a first intermediate section in fluid communication with the at least one water input section and a second intermediate section in fluid communication with the at least one water output section.

23. The controller according to claim 21, wherein the heat sink body provides an inlet to the at least one intermediate section, and the inlet is selectively sealed by a sealing member.

24. The controller according to claim 21, wherein the heat sink body comprises a heat dissipation surface, and at least part of the controller is mounted on the heat dissipation surface.

25. The controller according to claim 24, wherein part of the printed circuit board and the at least one intermediate section overlap.

26. The controller according to claim 24, wherein the electronic components of the controller comprise power semiconductor devices, the power semiconductor devices and the at least one intermediate section overlapping.
